(19) United States
(12) Patent Application Publication
(10) Pub. No.: US 2017/0116921 A1
(43) Pub. Date: Apr. 27, 2017

(54) SHIFT REGISTER UNIT, GATE DRIVE CIRCUIT USING THE SAME AND DISPLAY DEVICE USING THE SAME

(71) Applicant: EVERDISPLAY OPTRONICS (SHANGHAI) LIMITED, SHANGHAI CITY (CN)

(72) Inventors: Lina XIAO, SHANGHAI CITY (CN); Xingyu ZHOU, SHANGHAI CITY (CN)

(73) Assignee: EVERDISPLAY OPTRONICS (SHANGHAI) LIMITED, SHANGHAI CITY (CN)

(21) Appl. No.: 15/224,957

(22) Filed: Aug. 1, 2016

(30) Foreign Application Priority Data
Oct. 22, 2015 (CN) 201510690101.0

(51) Int. Cl. G09G 3/3258; G11C 19/28; G09G 3/3266

(52) U.S. Cl. CPC G09G 3/3258; G09G 3/3266; G11C 19/28; G09G 2310/08; G09G 2300/0852; G09G 2310/0286; G09G 2320/02

(57) ABSTRACT

A shift register unit, a gate drive circuit and a display device are provided. The shift register unit is composed of a first to seventh transistor and a first and second capacitor. Compared with the prior art, the present disclosure cuts down two transistors, but the output signal of the shift register unit is not influenced on. Therefore, the present disclosure may reduce the wiring area of the shift register unit and the gate drive circuit composed of the shift register unit, and provide technical support for achieving display devices with higher resolutions and narrower frames. Meanwhile, the structure of the shift register unit and the gate drive circuit composed of the shift register units are simplified, such that preparation process may be simplified, and preparation cost may be reduced.

### CROSS-REFERENCE TO RELATED APPLICATIONS

The present application is based upon and claims priority to Chinese Patent Application No. 201510690101.0, filed Oct. 22, 2015, the entire contents of which are incorporated herein by reference.

### TECHNICAL FIELD

The present disclosure generally relates to a field of display technology, and more particularly, to a shift register unit, a gate drive circuit using the shift register unit and a display device using the gate drive circuit.

### BACKGROUND

Compared with a liquid crystal display panel in the conventional technology, an OLED (Organic Light Emitting Diode) display panel has characteristics of faster response, better color purity and brightness, higher contrast, wider visual angle and so on. Therefore, display technology developers are paying increasingly more attention to it. However, OLED display panels in the prior art still need to be improved.

Display of the OLED display panel is mainly realized by a pixel matrix. Generally, pixels of each row are connected to a corresponding scan gate line. During operating process of the OLED display panel, input signals are converted to on/off control signals via conversion of the shift register unit of the gate drive circuit, and then successively applied to respective scan gate lines of the OLED display panels, thereby strobing the pixels of each row. For example, FIG. 1 is a circuit structure of a common shift register unit in the prior art. The shift register unit is composed of nine transistors (the first transistor M1 to the ninth transistor M9) and two capacitor elements (the first capacitor C1 and the second capacitor C2).

With development of the flat panel display technology, products with high resolutions and narrow frames have attracted more and more attention of people. However, a large amount of transistors in the shift register unit in the prior art will occupy large wiring area, which is disadvantageous to the increasing of effective display area and to the narrow frame design; in addition, more transistors increase the preparation process difficulty of the shift register unit, and increase preparation cost.

### SUMMARY

Aiming at least a part of the above problems in the prior art, the present disclosure provides a shift register unit with a simpler structure, a gate drive circuit using the shift register unit and a display device using the gate drive circuit, to reduce the wiring area of the gate drive circuit.

The other characteristics and advantages of the present disclosure will become apparent from the following description, or in part, may be learned by the practice of the present disclosure.

According to a first aspect of the present disclosure, there is provided a shift register unit, including:

a first transistor to a seventh transistor;

a first capacitor and a second capacitor;

a first clock signal end;

an input end;

a first node;

a first voltage end;

a second node;

a second voltage end;

an output end; and

a second clock signal end,

wherein:

a gate electrode of the first transistor is connected with the first clock signal end, a source electrode of the first transistor is connected with the input end, and a drain electrode of the first transistor is connected with a source electrode of the second transistor,

a gate electrode of the second transistor is connected with the first clock signal end, and a drain electrode of the second transistor is connected with the first node,

a gate electrode of the third transistor is connected with the first clock signal end, a source electrode of the third transistor is connected with the first voltage end, and a drain electrode of the third transistor is connected with a second node,

a gate electrode of the fourth transistor is connected with a drain electrode of the fifth transistor, a source electrode of the fourth transistor is connected with the first clock signal end, and a drain electrode of the fourth transistor is connected with the second node,

a gate electrode of the fifth transistor is connected with the first voltage end, and a source electrode of the fifth transistor is connected with the first node,

a gate electrode of the sixth transistor is connected with the second node, a source electrode of the sixth transistor is connected with the second voltage end, and a drain electrode of the sixth transistor is connected with the output end,

a gate electrode of the seventh transistor is connected with the first node, a source electrode of the seventh transistor is connected with a second clock signal end, and a drain electrode of the seventh transistor is connected with the output end,

a first end of the first capacitor is connected with the second voltage end, and a second end of the first capacitor is connected with the second node; and

a first end of the second capacitor is connected with the first node, and a second end of the second capacitor is connected with the output end.

According to a second aspect of the present disclosure, there is provided a gate drive circuit, including any one of the above shift register units according to the first aspect.

According to a third aspect of the present disclosure, there is provided a display device, including any one of the above gate drive circuits according to the second aspect.

According to exemplary implementations of the present disclosure, the shift register unit is composed of seven transistors and two capacitors. Compared with the prior art, the present disclosure cuts down two transistors, but the output signal of the shift register unit is not influenced on. Therefore, the present disclosure may reduce the wiring area of the shift register unit and the gate drive circuit composed of the shift register unit, and provide technical support for achieving display devices with higher resolutions and narrower frames. Meanwhile, the structure of the shift register unit and the gate drive circuit composed of the shift register units are simplified, such that preparation process may be simplified, and preparation cost may be reduced.

### BRIEF DESCRIPTION OF THE DRAWINGS

The exemplary implementations will be described in detail with reference to the accompanying drawings, through which the above and other features and advantages of the disclosure will become more apparent.

FIG. 1 is a schematic diagram of a circuit structure of a shift register unit in the prior art;

FIG. 2 is a schematic diagram of a circuit structure of a shift register unit according to an exemplary implementation of the present disclosure;

FIG. 3 is a schematic diagram of driving timings and signal waveforms of the shift register unit in FIG. 2;

FIG. 4 is a comparison result of an output signal waveform of the shift register unit in FIG. 2 and that of the shift register unit in the prior art;

FIG. 5 is an implementation structural schematic diagram of a gate drive circuit according to an exemplary implementation of the present disclosure; and

FIG. 6 is an implementation structural schematic diagram of a display device according to an exemplary implementation of the present disclosure.

### DESCRIPTION OF REFERENCE SIGNS

M1-M9: the first to ninth transistor

C1: the first capacitor

C2: the second capacitor

CKV1: the first clock signal

CKV2: the second clock signal

VEE: the first voltage end

VDD: the second voltage end

VIN: the input end

VOUT: the output end

N1: the first node

N2: the second node

1: the shift register unit

10: the gate drive circuit

100: the display device

### DESCRIPTION OF THE EMBODIMENTS

Exemplary implementations will now be described more fully with reference to the accompanying drawings. However, the exemplary implementations can be implemented in various forms and should not be understood as being limited to the embodiments set forth herein; on the contrary, these implementations are provided so that this disclosure will be thorough and complete, and the concept of exemplary implementations will be fully conveyed to those skilled in the art. In the drawings, the thicknesses of the regions and layers are exaggerated for clarity. In the drawings, the same reference signs denote the same or similar structure, thus their detailed description will be omitted.

In addition, the described features, structures or characteristics may be combined in one or more implementations in any suitable manner. In the following description, numerous specific details are provided so as to allow a full understanding of the implementations of the present disclosure. However, those skilled in the art will recognize that the technical solutions of the present disclosure may be practiced without one or more of the specific details, or other methods, components, connections and so on may be used. In other cases, the well-known structures, materials or operations are not shown or described in detail to avoid obscuring various aspects of the present disclosure.

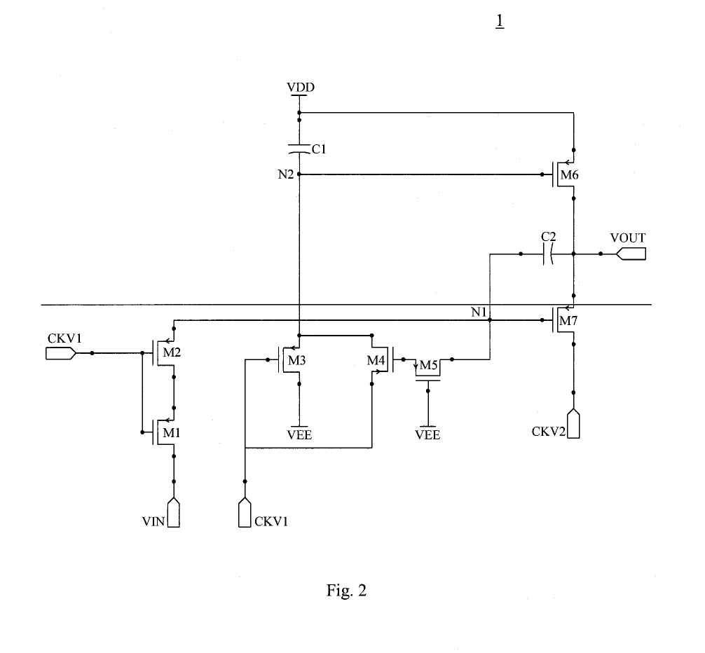

As shown in FIG. 2, a shift register unit is provided according to the present exemplary implementation. The shift register unit is composed of a first to seventh transistor and a first and second capacitor, wherein the first to seventh transistor are all P-channel type transistors. The specific circuit structure of the shift register unit may be as follows.

A gate electrode of the first transistor M1 is connected with a first clock signal end, a source electrode of the first transistor M1 is connected with an input end VIN, and a drain electrode of the first transistor M1 is connected with a source electrode of the second transistor M2. A gate electrode of the second transistor M2 is connected with the first clock signal end, and a drain electrode of the second transistor M2 is connected with a first node N1. When the first clock signal CKV1 is at a low level, the first transistor M1 and the second transistor M2 turn on, and an input signal of the input end VIN is output to the first node N1.

A gate electrode of the third transistor M3 is connected with the first clock signal end, a source electrode of the third transistor M3 is connected with a first voltage end VEE, and a drain electrode of the third transistor M3 is connected with a second node N2. When the first clock signal CKV1 is at a low level, the third transistor M3 turns on, and a voltage signal of the first voltage end VEE is output to the second node N2. According to the present exemplary implementation, the voltage signal of the first voltage end VEE is a low level signal.

A gate electrode of the fourth transistor M4 is connected with a drain electrode of the fifth transistor M5, a source electrode of the fourth transistor M4 is connected with the first clock signal CKV1, and a drain electrode of the fourth transistor M4 is connected with the second node N2. A gate electrode of the fifth transistor M5 is connected with the first voltage end VEE, and a source electrode of the fifth transistor M5 is connected with the first node N1. A voltage signal of the first node N1 is applied to the gate electrode of the fourth transistor M4 via the fifth transistor M5 to control on-off of the fourth transistor M4. When the voltage signal of the first node N1 is at a low level, the first clock signal CKV1 is output to the second node N2 via the fourth transistor M4.

A gate electrode of the sixth transistor M6 is connected with the second node N2, a drain electrode of the sixth transistor M6 is connected with a second voltage end VDD, and a source electrode of the sixth transistor M6 is connected with an output end VOUT. According to the present exemplary implementation, a voltage signal of second voltage end VDD is a high level signal. When a voltage signal of the second node N2 is at a low level, the voltage signal of the second voltage end VDD is output to the output end VOUT, such that a signal output by the output end VOUT is at a high level.

A gate electrode of the seventh transistor M7 is connected with the first node N1, a source electrode of the seventh transistor M7 is connected with a second clock signal end, and a drain electrode of the seventh transistor M7 is connected with the output end VOUT. When the voltage signal of the first node N1 is at a low level and a second clock signal CKV2 is at a low level, the seventh transistor M7 turns on, and the second clock signal CKV2 is input to the output end VOUT via the seventh transistor M7, such that the signal output by the output end VOUT is at a low level.

A first end of the first capacitor C1 is connected with the second voltage end VDD, and a second end of the first capacitor C1 is connected with the second node N2. A first end of the second capacitor C2 is connected with the first node N1, and a second end of the second capacitor C2 is connected with the output end VOUT.

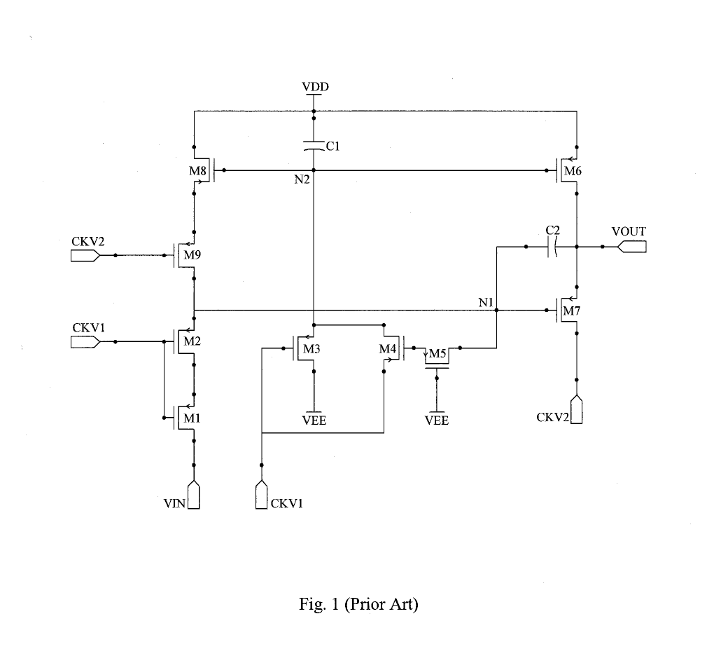

After two transistors in the prior art (i.e. the eighth transistor M8 and the ninth transistor M9 in FIG. 1) are removed, a capacitance value of the second capacitor C2 is adjusted according to the present exemplary implementation. For example, a capacitance value of the second capacitor C2 in the prior art is 0.01 pF, while the capacitance value of the second capacitor C2 according to the present exemplary implementation is greater than 0.05 pF, for example, the capacitance value of the second capacitor C2 may be 0.1 pF or the like.

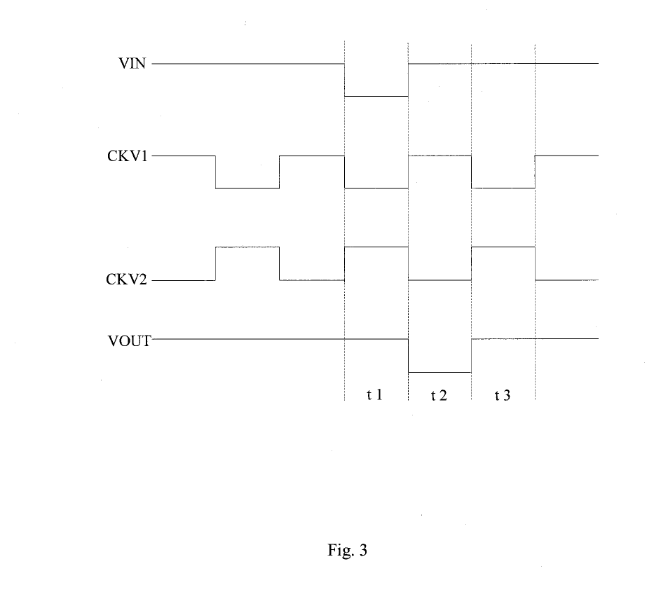

The operating principle of the shift register unit according to the present exemplary implementation is illustrated more detailedly in combination with the driving timing diagram as shown in FIG. 3 below. For example, it may include the following stages.

In a charging stage t1, the input signal of the input end VIN and the first clock signal CKV1 are at a low level, and the second clock signal CKV2 is at a high level. The first transistor M1, the second transistor M2, the third transistor M3 and the fifth transistor M5 are turned on. The input signal is input to the first node N1 via the first transistor M1 and the second transistor M2, to charge the second capacitor C2, and turn on the fourth transistor M4 and the seventh transistor M7 at the same time. The voltage signal of the first voltage end VEE is input to the second node N2 via the third transistor M3, and the first clock signal CKV1 is input to the second node N2 via the fourth transistor M4, to turn on the sixth transistor M6. The second clock signal CKV2 is input to the output end VOUT via the seventh transistor M7, the signal of the second voltage end VDD is input to the output end VOUT via the sixth transistor M6, and the output end VOUT outputs a high level signal.

In an output stage t2, the input signal of the input end VIN and the first clock signal CKV1 are at a high level, and the second clock signal CKV2 is at a low level. The first transistor M1, the second transistor M2 and the third transistor M3 are turned off. Under an effect of a low level voltage signal stored in the second capacitor C2, the voltage of the first node N1 is still at a low level, thus the fourth transistor M4, the fifth transistor M5 and the seventh transistor M7 are kept on being on. The first clock signal CKV1 is output to the second node N2 via the fourth transistor M4, such that a potential of the second node N2 rises, and the sixth transistor M6 is turned off. The second clock signal CKV2 is input to the output end VOUT via the seventh transistor M7, and the output end VOUT outputs a low level signal.

In a reset stage t3, the input signal of the input end VIN and the second clock signal CKV2 are at a high level, and the first clock signal CKV1 is at a low level. The first transistor M1, the second transistor M2, the third transistor M3 and the fifth transistor M5 are turned on. The input signal is input to the first node N1 via the first transistor M1 and the second transistor M2, to discharge the second capacitor C2, and turn off the fourth transistor M4 and the seventh transistor M7 at the same time. The voltage signal of the first voltage end VEE is input to the second node N2 via the third transistor M3, and the sixth transistor M6 is turned on. The signal of the second voltage end VDD is input to the output end VOUT via the sixth transistor M6, and the output end VOUT outputs a high level signal.

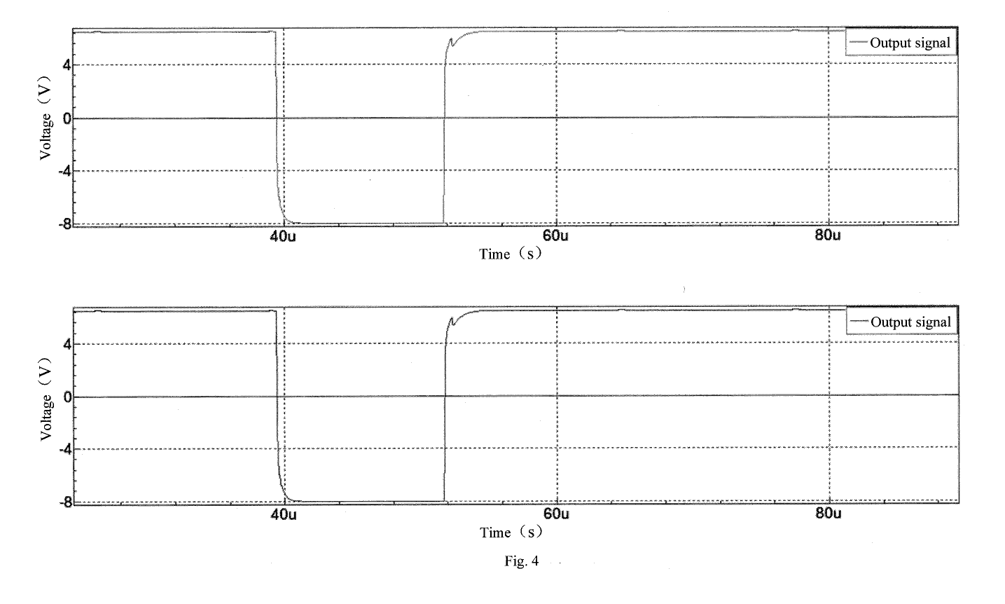

Further, the inventor also makes experimental verification on the technical effect of the present disclosure. FIG. 4 is a comparison result of output signal waveform of the shift register unit according to the present exemplary implementation and that of the shift register unit in the prior art. It can be seen that, although two transistors are removed from the shift register unit according to the present exemplary implementation, the same output signal may be output as that by the shift register unit in the prior art, that is, the performance of the gate drive circuit is not influenced on much.

The additional advantage of the shift register unit and the gate drive circuit according to the present exemplary implementation is the use of a single channel type of transistors, i.e., all the transistors are P-channel type transistors, which reduces complexity of preparation technology and production cost. The shift register unit provided by the present disclosure may be changed to all N-channel type transistors (for example, all the transistors are to be N-channel type transistors; the above first voltage end VEE is to be a high level end of the power supply, and the above second voltage end VDD is to be a low level end of the power supply), which is not limited to the implementation provided by the present exemplary implementation, and will not be repeatedly illustrated herein.

Above all, in the shift register unit provided by exemplary implementations of the present disclosure, the shift register unit is composed of seven transistors and two capacitors. Compared with the prior art, the present disclosure cuts down two transistors, but the output signal of the shift register unit is not influenced on. Therefore, the present disclosure may reduce the wiring area of the shift register unit and the gate drive circuit composed of the shift register unit, and provide technical support for achieving display devices with higher resolutions and narrower frames. Meanwhile, the structure of the shift register unit and the gate drive circuit composed of the shift register units are simplified, such that preparation process may be simplified, and preparation cost may be reduced.

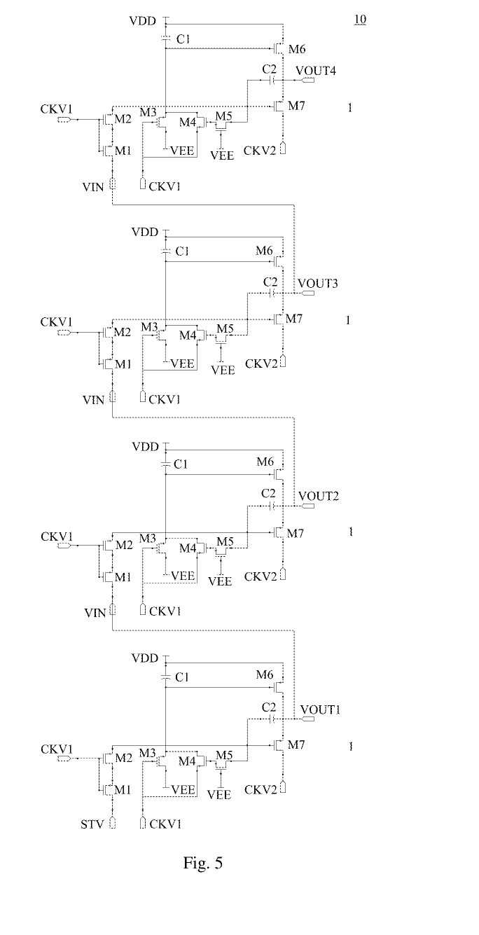

Further, the present exemplary implementation also provides a gate drive circuit 10, including any one of the above shift register units. Since the used shift register unit has fewer transistors, the gate drive circuit needs smaller wiring area. Specifically, the gate drive circuit according to the present exemplary implementation may be shown as FIG. 5, including a plurality of the shift register units 1, each of which is the same as that described in FIG. 2, wherein, except for the last level of the shift register units, the output end of each level of the shift register units is connected with the input end of the next level of the shift register units correspondingly, and the input end of the first level of the shift registers is connected with an initial signal STV.

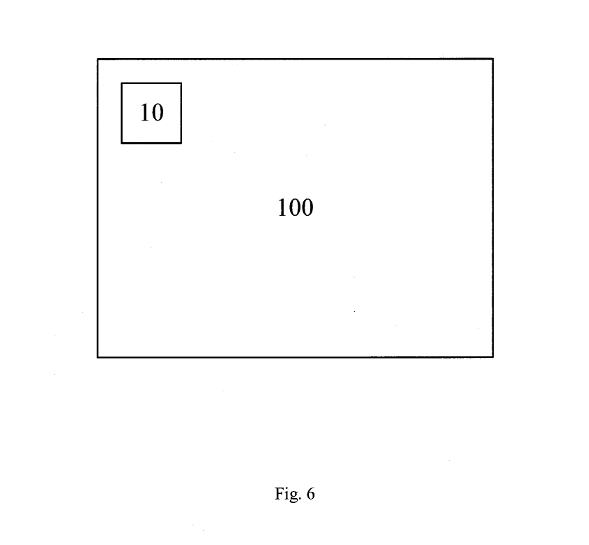

Further, the present exemplary implementation also provides a display device 100. Specifically, the display device 100 according to the present exemplary implementation may be shown as FIG. 6, including any one of the above gate drive circuits 10. Because the used the gate drive circuit has smaller wiring area, the effective display area of the display device may be increased, which is beneficial for improving the resolution of the display panel, and meanwhile, the frame of the display device may be made narrower.

The present disclosure has been described by the above related exemplary implementation, while the above implementation is only an example of implementing the present disclosure. It should be pointed out that the disclosed implementation does not limit the scope of the present disclosure. Instead, changes or modifications without departing from the spirit and scope of the present disclosure all belong to the patent protection scope of the present disclosure.

What is claimed is:

1. A shift register unit, comprising:
a first transistor to a seventh transistor;
a first capacitor and a second capacitor;
a first clock signal end;
an input end;
a first node;
a first voltage end;
a second node;
a second voltage end;
an output end; and
a second clock signal end,
wherein:
a gate electrode of the first transistor is connected with the first clock signal end, a source electrode of the first transistor is connected with the input end, and a drain electrode of the first transistor is connected with a source electrode of the second transistor,
a gate electrode of the second transistor is connected with the first clock signal end, and a drain electrode of the second transistor is connected with the first node,
a gate electrode of the third transistor is connected with the first clock signal end, a source electrode of the third transistor is connected with the first voltage end, and a drain electrode of the third transistor is connected with a second node,
a gate electrode of the fourth transistor is connected with a drain electrode of the fifth transistor, a source electrode of the fourth transistor is connected with the first clock signal end, and a drain electrode of the fourth transistor is connected with the second node,
a gate electrode of the fifth transistor is connected with the first voltage end, and a source electrode of the fifth transistor is connected with the first node,
a gate electrode of the sixth transistor is connected with the second node, a source electrode of the sixth transistor is connected with the second voltage end, and a drain electrode of the sixth transistor is connected with the output end,
a gate electrode of the seventh transistor is connected with the first node, a source electrode of the seventh transistor is connected with a second clock signal end, and a drain electrode of the seventh transistor is connected with the output end,
a first end of the first capacitor is connected with the second voltage end, and a second end of the first capacitor is connected with the second node; and
a first end of the second capacitor is connected with the first node, and a second end of the second capacitor is connected with the output end.

2. The shift register unit according to claim 1, wherein all the transistors are P-channel type transistors, the first voltage end is a low level end of a power supply, and the second voltage end is a high level end of the power supply.

3. The shift register unit according to claim 1, wherein all the transistors are N-channel type transistors; the first voltage end is a high level end of a power supply, and the second voltage end is a low level end of the power supply.

4. The shift register unit according to claim 1, wherein a capacitance value of the second capacitor is greater than 0.05 pF.

5. A gate drive circuit, comprising the shift register unit according to claim 1.

6. The gate drive circuit according to claim 5, wherein all the transistors are P-channel type transistors, the first voltage end is a low level end of a power supply, and the second voltage end is a high level end of the power supply.

7. The gate drive circuit according to claim 5, wherein all the transistors are N-channel type transistors; the first voltage end is a high level end of a power supply, and the second voltage end is a low level end of the power supply.

8. The gate drive circuit according to claim 5, wherein a capacitance value of the second capacitor is greater than 0.05 pF.

9. The gate drive circuit according to claim 5, wherein the gate drive circuit comprises a plurality of the shift register units, wherein, except for a last level of the shift register units, an output end of each level of the shift register units is connected with an input end of a next level of the shift register units correspondingly, and an input end of a first level of the shift registers is connected with an initial signal.

10. The gate drive circuit according to claim 6, wherein the gate drive circuit comprises a plurality of the shift register units, wherein, except for a last level of the shift register units, an output end of each level of the shift register units is connected with an input end of a next level of the shift register units correspondingly, and an input end of a first level of the shift registers is connected with an initial signal.

11. The gate drive circuit according to claim 7, wherein the gate drive circuit comprises a plurality of the shift register units, wherein, except for a last level of the shift register units, an output end of each level of the shift register units is connected with an input end of a next level of the shift register units correspondingly, and an input end of a first level of the shift registers is connected with an initial signal.

12. The gate drive circuit according to claim 8, wherein the gate drive circuit comprises a plurality of the shift register units, wherein, except for a last level of the shift register units, an output end of each level of the shift register units is connected with an input end of a next level of the shift register units correspondingly, and an input end of a first level of the shift registers is connected with an initial signal.

13. A display device, comprising the gate drive circuit according to claim 5.

14. The display device according to claim 13, wherein all the transistors are P-channel type transistors, the first voltage end is a low level end of a power supply, and the second voltage end is a high level end of the power supply.

15. The display device according to claim 13, wherein all the transistors are N-channel type transistors; the first voltage end is a high level end of a power supply, and the second voltage end is a low level end of the power supply.

16. The display device according to claim 13, wherein a capacitance value of the second capacitor is greater than 0.05 pF.

17. The display device according to claim 13, wherein the gate drive circuit comprises a plurality of the shift register units, wherein, except for a last level of the shift register units, an output end of each level of the shift register units is connected with an input end of a next level of the shift register units correspondingly, and an input end of a first level of the shift registers is connected with an initial signal.

18. The display device according to claim 14, wherein the gate drive circuit comprises a plurality of the shift register units, wherein, except for a last level of the shift register units, an output end of each level of the shift register units is connected with an input end of a next level of the shift register units correspondingly, and an input end of a first level of the shift registers is connected with an initial signal.

19. The display device according to claim 15, wherein the gate drive circuit comprises a plurality of the shift register units, wherein, except for a last level of the shift register units, an output end of each level of the shift register units is connected with an input end of a next level of the shift register units correspondingly, and an input end of a first level of the shift registers is connected with an initial signal.

20. The display device according to claim 16, wherein the gate drive circuit comprises a plurality of the shift register units, wherein, except for a last level of the shift register units, an output end of each level of the shift register units is connected with an input end of a next level of the shift register units correspondingly, and an input end of a first level of the shift registers is connected with an initial signal.
